(19) United States
(12) Patent Application Publication
(10) Pub. No.: US 2010/0038746 A1
(43) Pub. Date: Feb. 18, 2010

(54) SEMICONDUCTOR STRUCTURE AND METHOD FOR MAKING ISOLATION STRUCTURE THEREIN

(76) Inventor: Yi-Nan Su, Tao-Yuan City (TW)

Correspondence Address: NORTH AMERICA INTELLECTUAL PROPERTY CORPORATION, P.O. BOX 506, MERRIFIELD, VA, 22116, US

(21) Appl. No.: 12/190,568

(22) Filed: Aug. 12, 2008

(51) Int. Cl. H01L 21/76; H01L 23/58

(52) U.S. Cl. 257/513; 438/427; 257/E21.548; 257/E23.002

(57) ABSTRACT

A method for an isolation structure is provided. First, a substrate with a shallow trench isolation is provided. Second, a patterned mask is formed on the substrate. Then, the substrate is etched using the patterned mask to respectively form a first deep trench and a second deep trench as well as a first undercut and a second undercut on opposite sides of the shallow trench isolation. Later, the first deep trench and the second deep trench are partially filled with Si. Afterwards, the first deep trench and the second deep trench are filled with an isolation material to form the isolation structure.

### BACKGROUND OF THE INVENTION

1. Field of the Invention

The present invention relates to a semiconductor structure and a method for forming an isolation structure therein. In particular, the present invention relates to a semiconductor structure with passing gates and a method for forming a passing gate isolation (PGI) structure.

2. Description of the Prior Art

In the development of DRAM process, word lines are arranged to pass over other trench capacitors which are not controlled by this word line in order to increase the element density on the chip and enhance the integration effectively. FIG. 1 illustrates the word lines passing over other trench capacitors which are not controlled by this word line. As shown in FIG. 1, on the layout pattern, each word line 101 passes other adjacent non-active areas over the active area 102, the deep trench capacitors 103 and the shallow trench isolations (STI). Before the deep trench capacitors 103 are actually formed, there are only the shallow trench isolations and the active area 102 in/on the substrate because any non-STI region is an active area. Such word lines that pass over the non-active areas and the deep trench capacitors are called “passing gates 104” because the gate elements are only formed on the overlapping regions of the word lines 101 and the active area 102.

A layer of an insulation structure must be constructed between the passing gates and the deep trench capacitors to ensure the electrical insulation between the passing gates and the deep trench capacitors because the passing gates and the deep trench capacitors both are electrical elements and the passing gates need to pass over the deep trench capacitors of other memory cells. As shown in FIG. 1, the insulation 105 in fact serves as the electrical insulation between the passing gates 104 and the deep trench capacitors 103. It should be noted that merely one insulation structure is shown on FIG. 1 and other incomplete insulation structures are omitted, which suggests other insulation structures may also exist on other deep trench capacitors.

Sequentially speaking, the shallow trench isolation is formed first, next the deep trench capacitors then the insulation structure of the passing gates are defined when the passing gates pass over the shallow trench isolation and the deep trench capacitors. FIGS. 2-8 illustrate the conventional steps to form the insulation structure of the passing gates. First, as shown in FIG. 2, the deep trench capacitor 113 is formed after the shallow trench isolation 112 is formed in the substrate 111. The steps to form the deep trench capacitor 113 may be the profile of the deep capacitor trench is first formed by etching, next the bottom of the capacitor trench is enlarged to form a bottle shape to pursue a larger inner surface, afterwards other elements such as the collar oxide is formed, and then the capacitor trench is filled with a conductive material, such as silicon. After the deep trench capacitor 113 is formed, other necessary processes such as ion well (not shown) implantation, cleaning, or thermal annealing are performed. Secondly, as shown in FIG. 3 the pad oxide layer 114 and the silicon nitride layer 115 are sequentially formed on the substrate 111 to facilitate the formation of the photo-mask to define the location of the insulation structure. Afterwards, as shown in FIG. 4, the BARC layer 116 is formed and a patterned photoresist 117 is formed to define the location of the insulation structure for the passing gates. In the meantime, the photoresist 117 should precisely cover the shallow trench isolation 112 and the deep trench capacitor 113 to ensure the insulation structure for the passing gates is in the correct position.

Then, as shown in FIG. 5, part of the BARC layer 116 and the silicon nitride layer 115 are removed by etching. Next, as shown in FIG. 6, the remaining photoresist 117 and the BARC layer 116 are removed to leave the required silicon nitride layer 115 and the pad oxide layer 114. In the meantime the silicon nitride layer 115 serves as a hard mask. Thereafter, as shown in FIG. 7, the pad oxide layer 114 which is not masked by the silicon nitride layer 115 is removed by etching using the silicon nitride layer 115 as the hard mask. Afterwards, in FIG. 8, a gate oxide layer (not shown) is formed and the gate 110 is formed on the gate oxide layer and the passing gate 120 is formed on the silicon nitride layer 115 conventionally. Theoretically speaking, the passing gate 120 now is supposed to be formed on the deep trench capacitor 113. In other words, the silicon nitride layer 115 and the pad oxide layer 114 which are not removed in FIG. 7 now serve as the insulation structure 121 for the passing gate 120. The gate 110 is useful in controlling the deep trench capacitor 113 to form a memory cell. This way, the insulation structure 121 ensures that an excellent insulation is established between the passing gate 220 and the underlying deep trench capacitor 113 to avoid shorts and to avoid interfering with the performance of the DRAM.

However, the above-mentioned procedure not only requires an additional mask to define the position of the insulation structure 121, moreover it is extremely difficult to define the insulation structure 121, i.e. the pad oxide layer 114 and the silicon nitride layer 115, above the deep trench capacitor 113 with little misalignment. Furthermore, there is no sufficient protection to keep the exposed shallow trench isolation 112 and the deep trench capacitor 113 from the possible damages resulting from the ion well implantation, cleaning, or thermal annealing before the completion of the insulation structure 121.

Therefore, a novel method for forming an insulation structure is needed to eliminate an additional mask to define the position of the insulation structure, to get rid of the misalignment between the insulation structure and the previously-established deep trench capacitor, and further to protect the substrate, the shallow trench isolation and the deep trench capacitor from exposure and from the collateral damages brought about by the formation of other regions before the completion of the insulation structure.

### SUMMARY OF THE INVENTION

The present invention therefore proposes a semiconductor structure and a method for forming an isolation structure therein. The isolation structure of the present invention is constructed in a deep trench with an undercut trait. The undercut trait would be further enlarged to be a void so as to serve as an opening for the electrical connection between the exterior contact plug and the interior conductive material in the deep trench capacitor when a patterned mask for the protection of the substrate, for the shallow trench isolation and for the deep trench capacitor is removed.

The present invention therefore first proposes a semiconductor structure. The semiconductor structure includes substrate, a first deep trench, a second deep trench, a shallow trench isolation, a first conductive material, a second conductive material, a first isolation structure, a second isolation structure, a first deep trench extension region, a second deep trench extension region, a gate structure, a dielectric layer, a first contact plug, and a second contact plug. The substrate includes a first deep trench, a second deep trench and a shallow trench isolation sandwiched between the first deep trench and the second deep trench. The first conductive material partially fills the first deep trench. The second conductive material also partially fills the second deep trench. The first isolation layer is disposed on the first conductive material, filling the first deep trench and partially exposing the first conductive material, wherein the first isolation layer serves as an isolation structure. The second isolation layer is disposed on the second conductive material, filling the second deep trench and partially exposing the second conductive material, wherein the second isolation layer also serves as an isolation structure. The gate structure is disposed on at least one of the first isolation layer and the second isolation layer. The dielectric layer covers the substrate, the first isolation layer, the second isolation layer and the gate structure. The first contact plug is disposed in the dielectric layer and electrically connected to the first conductive material. The second contact plug is disposed in the dielectric layer and electrically connected to the second conductive material.

The present invention again proposes a method for forming an isolation structure in a semiconductor structure. First, a substrate is provided. There is a shallow trench isolation in the substrate. Second, a patterned mask layer is formed on the substrate. Then, the substrate is etched through the patterned mask layer to form a first deep trench and a second deep trench respectively on two sides of the shallow trench isolation and to form a first undercut and a second undercut adjacent to the patterned mask layer. Later, the first deep trench and the second deep trench are partially filled with silicon. Afterwards, two isolation structures are formed by filling the first deep trench and the second deep trench with a first isolation material. Thereafter, the patterned mask layer is removed so that the first isolation material bulges from the surface of the substrate and the first undercut and the second undercut are respectively enlarged to form a first void and a second void.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 illustrates the word lines passing over other trench capacitors which are not controlled by this word line.

FIGS. 2-8 illustrate the conventional steps to form the insulation structure of the passing gates.

FIGS. 9-16 illustrate the method for forming the isolation structure in a semiconductor structure of the present invention.

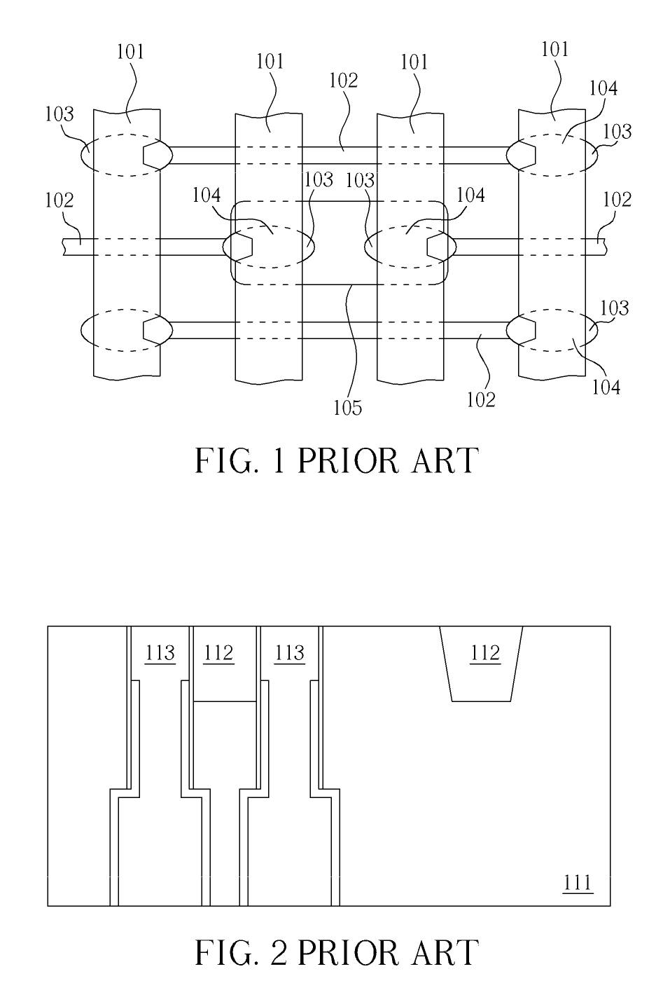

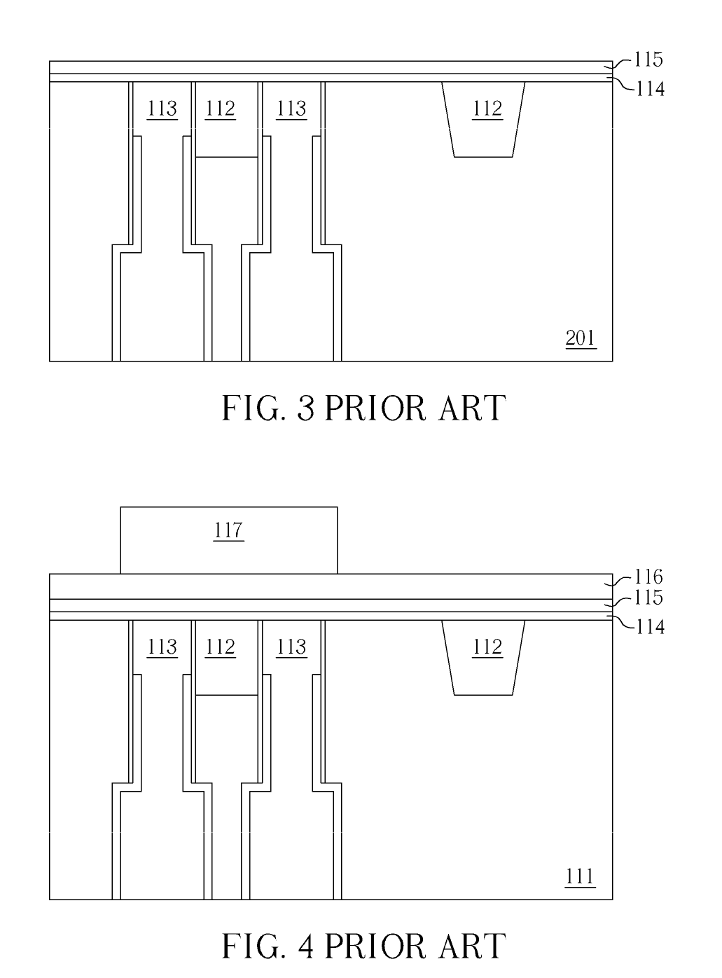

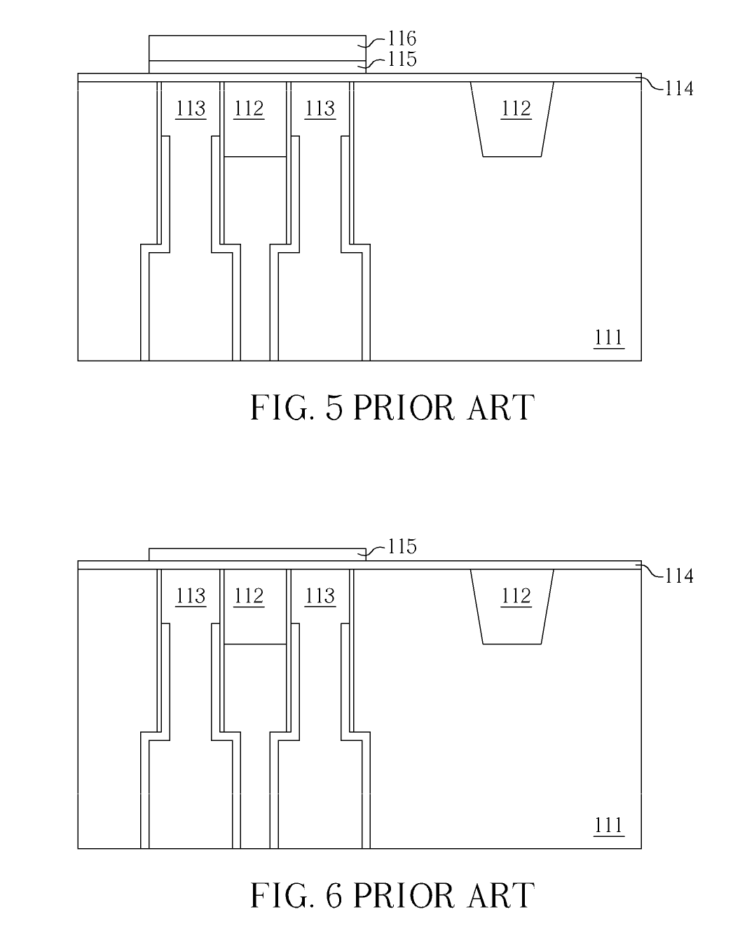

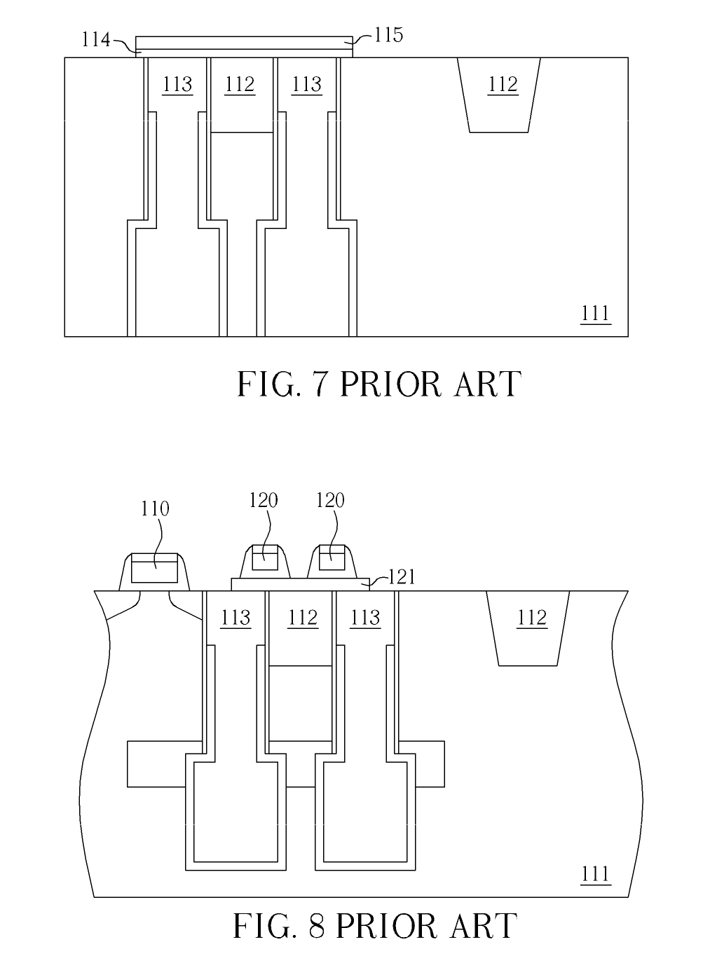

### DETAILED DESCRIPTION

The present invention provides a semiconductor structure and a method for forming an isolation structure therein. In the novel method of the present invention, an additional mask to define the position of the insulation structure may be eliminated. In addition, the novel method also gets rid of the misalignment problem between the isolation structure and the previously-established deep trench capacitor. Further, the substrate, the shallow trench isolation and the deep trench capacitors will not be exposed before the completion of the isolation structure, which protects the shallow trench isolation and the deep trench capacitors from the collateral damages of the processes such as ion well implantation, cleaning, or thermal annealing. Moreover, the isolation structure of the present invention is constructed in a deep trench with an undercut trait. The undercut trait would be further enlarged to be a void so as to serve as an opening for the electrical connection between the exterior contact plug and the interior conductive material in the deep trench capacitor.

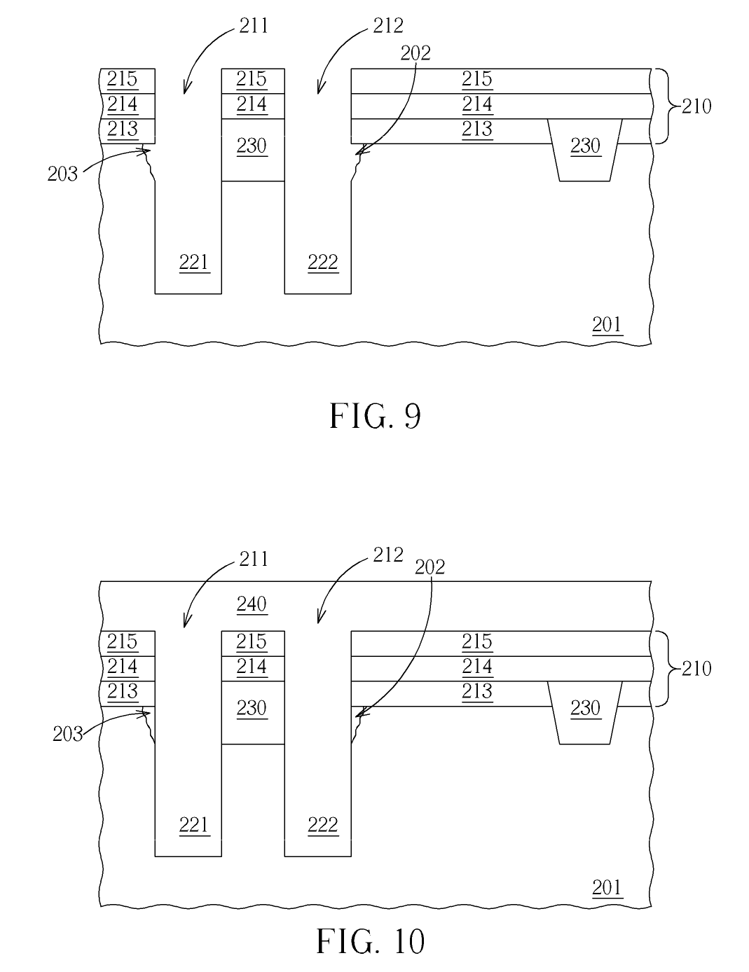

The present invention first provides a method for forming an isolation structure in a semiconductor structure. FIGS. 9-16 illustrate the method for forming the isolation structure in a semiconductor structure of the present invention. To begin with, as shown in FIG. 9, a substrate 201 is provided. A patterned mask layer 210 covers the substrate 201. The patterned mask layer 210 further includes a first opening 211 and a second opening 212. The first opening 211 defines the location of a first deep trench 221 in the substrate 201. Similarly, the second opening 212 defines the location of a second deep trench 222 in the substrate 201. In addition, a shallow trench isolation 230 is sandwiched between the first deep trench 221 and the second deep trench 222.

The substrate 201 is usually a semiconductor substrate, such as Si. The patterned mask layer 210 may include a single layer structure or multiple layers structure. For example, the patterned mask layer 210 includes a patterned pad layer 213, a patterned buffer layer 214 and a patterned oxide layer 215. The patterned pad layer 213 and the patterned buffer layer 214 may each include a nitride, such as silicon nitride. The patterned oxide layer 215 includes silicon oxide. The patterned mask layer 210 not only serves to define the location of the first deep trench 221 and the second deep trench 222, but also protects the substrate 201 and the shallow trench isolation 230 from the subsequent damages.

The method for forming the first deep trench 221 and the second deep trench 222 in the substrate 201 may be as follows. First, the shallow trench isolation 230 is formed in advance in the substrate 201. Second, the patterned mask layer 210 is formed on the surface of the substrate 201 to define the location of the first deep trench 221 and the second deep trench 222, preferably located on two sides of the shallow trench isolation 230 and partially overlapped with the shallow trench isolation 230. Later, the substrate 201 and part of the shallow trench isolation 230 are etched by means of the patterned mask layer 210 to respectively form the first deep trench 221 and the second deep trench 222 located by two opposing sides of the shallow trench isolation 230 in the substrate 201. During the etching of the first deep trench 221 and the second deep trench 222, the etching recipe may be optionally formulated to form some undercut 202, 203 adjacent to the patterned mask layer 210 near the surface of the substrate 201, which is one of the features of the present invention.

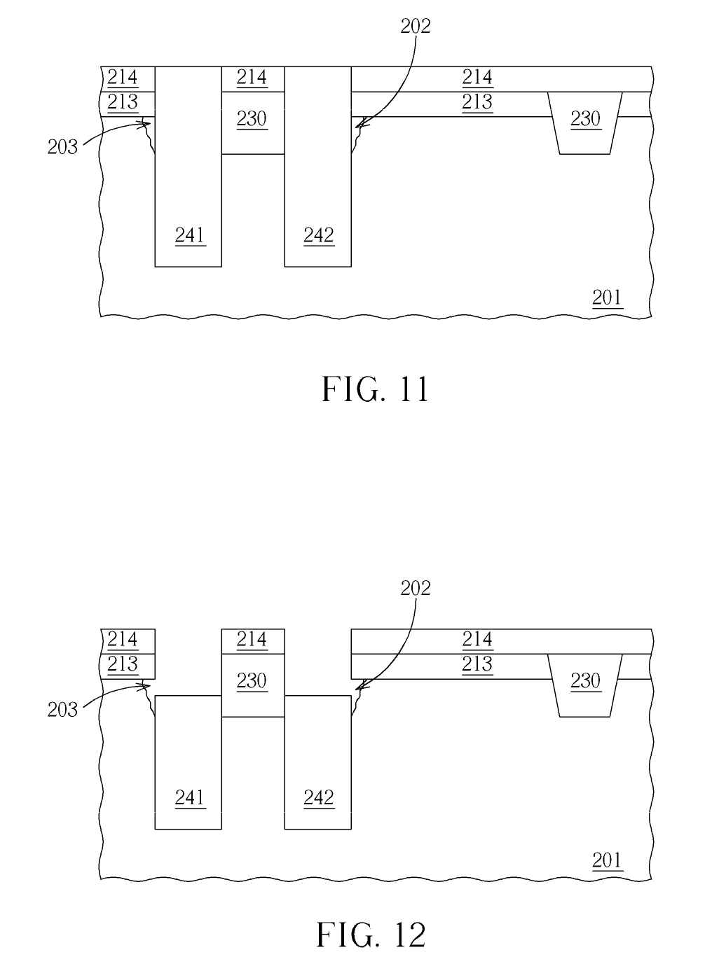

After the first deep trench 221 and the second deep trench 222 are formed in the substrate 201, a conductive material and an isolation material are used to respectively fill the first deep trench 221 and the second deep trench 222. For example, as shown in FIG. 10, first a conductive material 240, such as Si, blanket covers the substrate 201 and simultaneously fills the first deep trench 221 and the second deep trench 222. Then, as shown in FIG. 11, the excess conductive material 240 is removed by a chemical mechanical polishing (CMP) so that the conductive material 241, 242 respectively fills the first deep trench 221 and the second deep trench 222. Optionally, removing the excess conductive material 240 may simultaneously remove the patterned oxide layer 215. Afterwards, as shown in FIG. 12, a first etching-back is performed so that the conductive material 241, 242 respectively fills the first deep trench 221 and the second deep trench 222 with a proper depth.

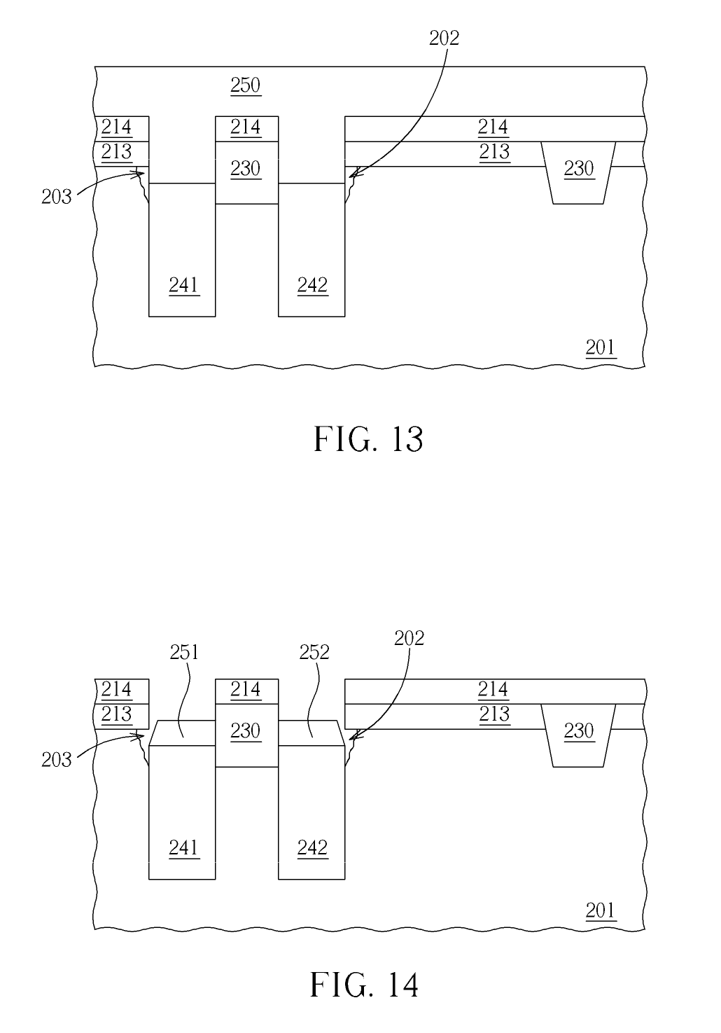

Later, a first isolation material 250 is partially formed in the first deep trench 221 and the second deep trench 222 to construct the required isolation structure 251, 252. The following is an example of constructing the required isolation structure 251, 252 in the first deep trench 221 and the second deep trench 222. First, as shown in FIG. 13, a first isolation material 250, such as silicon oxide, is blanket deposited on the substrate 201 and simultaneously fills the first deep trench 221 and the second deep trench 222 by high density plasma-chemical vapor deposition (HDP-CVD) or by plasma-enhanced chemical vapor deposition (PE-CVD). Then, as shown in FIG. 14, a second back-etching is performed to remove part of the first isolation material 250 so that the required isolation structure 251, 252 respectively fills the first deep trench 221 and the second deep trench 222 with a proper depth. So far, the required isolation structure 251, 252 for use in a semiconductor structure is completed.

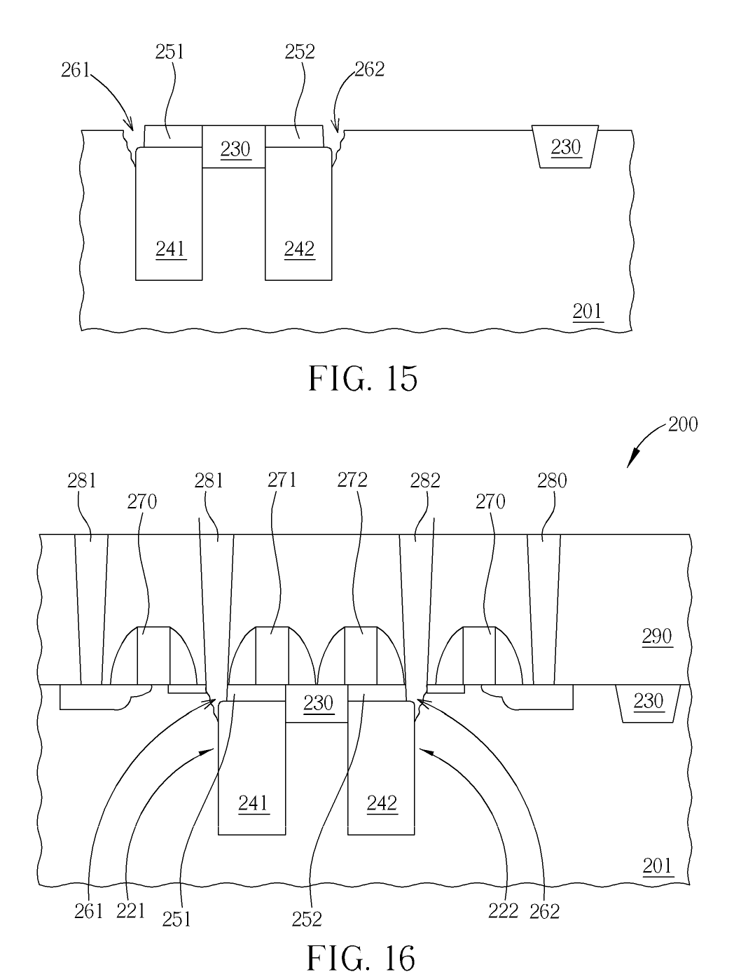

Afterwards, the remaining patterned mask layer 210 can be removed, such as the patterned pad layer 213 and the patterned buffer layer 214 as shown in FIG. 15. Because the surface of the isolation structure 251, 252 is higher than the surface of the substrate 201, the surface of the isolation structure 251, 252 bulges from the surface of the substrate 201 after the remaining patterned mask layer 210 is removed.

Then proper semiconductor processes can be performed to construct other semiconductor regions, such as logic regions, or semiconductor elements, such as gates, on the substrate 201 to complete the required semiconductor structures. Some proper semiconductor processes are an ion well process, a threshold voltage implantation process, a photoresist-removing process, a cleaning process, a gate structure process and a silicide process . . . etc. In addition, as shown in FIG. 16, a dielectric layer 290 may cover semiconductor elements, such as the substrate 201, the first isolation layer 251, the second isolation layer 252 and the gate structure 270. Contact plugs 280, 281, 282 penetrate the dielectric layer 290 to form the electrical connection between the semiconductor elements.

It should be noted that while the above semiconductor processes are carried out, the accompanied etching or cleaning procedure further enlarges the original undercut 202, 203 to form a self-alignment first void 261 and a self-alignment second void 262, or namely a first deep trench extension region 261 and a second deep trench extension region 262, in the first deep trench 221 and the second deep trench 222, which is another feature of the present invention. Because the first void 261 and the second void 262 which are enlarged from the original undercut 202, 203 expose partial surface of the conductive materials 241, 242, the first contact plug 281 and the second contact plug 282 therefore easily and conveniently connect to the conductive materials 241, 242 electrically.

Given the above, the present invention arranges the word lines which constitute gates passing the overhead of the first deep trench 221 and the second deep trench 222 to be the passing gates 271, 272. Because the isolation structure 251, 252 are in self-alignment on the conductive materials 241, 242 in the first deep trench 221 and the second deep trench 222, the isolation structure 251, 252 now serve as the passing gate isolation (PGI) to ensure a good electrical isolation between the gates and the conductive materials 241, 242. In such way, the passing gate isolation is formed by means of self-alignment and word lines may pass over the deep trenches which are not controlled by themselves to effectively boost up the element density.

A semiconductor structure 200 is therefore manufactured by the method of the present invention, as shown in FIG. 16. The semiconductor structure 200 includes substrate 201, a first deep trench 221, a second deep trench 222, a shallow trench isolation 230, a first conductive material 241, a second conductive material 242, a first isolation structure 251, a second isolation structure 252, a first deep trench extension region 261, a second deep trench extension region 262, a gate structure 270, passing gates 271, 272, a dielectric layer 290, a first contact plug 281, and a second contact plug 282.

The shallow trench isolation 230 is in the substrate 201 and sandwiched between the first deep trench 221 and the second deep trench 222. The first deep trench 221 and the second deep trench 222 are filled with the conductive material and the isolation structure, so the isolation structure 251, 252 together ensure a good electrical isolation between the passing gate 271, 272 and the first conductive material 241 and the second conductive material 242. In addition, by the isolation structure 251, 252 are the first deep trench extension region 261 and the second deep trench extension region 262 which are self-aligned in the deep trenches and on the conductive materials, so that the first contact plug 281 and the second contact plug 282 which penetrate the dielectric layer 290 may directly form the electrical connection to the first conductive material 241 and the second conductive material 242.

Those skilled in the art will readily observe that numerous modifications and alterations of the device and method may be made while retaining the teachings of the invention.

What is claimed is:

1. A method for forming an isolation structure, comprising:
providing a substrate with a patterned mask layer thereon, a first deep trench partially filled with silicon, a second deep trench partially filled with silicon and located adjacent to said first deep trench, and a shallow trench isolation disposed in said substrate and sandwiched between said first deep trench and said second deep trench, said patterned mask layer having a first opening defining said first deep trench and a second opening defining said second deep trench, wherein a first undercut and a second undercut are located in said substrate and respectively adjacent to said patterned mask layer;
partially filling said first deep trench and said second deep trench with a first isolation material to form said isolation structure; and
removing said patterned mask layer so that said first isolation material bulges from the surface of said substrate and said first undercut and said second undercut respectively form a first void and a second void.

2. The method of claim 1, wherein said patterned mask layer comprises a patterned pad layer and a patterned buffer layer.

3. The method of claim 2, wherein said patterned pad layer and said patterned buffer layer each comprise a nitride.

4. The method of claim 1, wherein said first isolation material comprises an oxide.

5. The method of claim 1, wherein said first isolation material is deposited by high density plasma-chemical vapor deposition (HDP-CVD).

6. The method of claim 1, wherein said first isolation material is deposited by plasma-enhanced chemical vapor deposition (PE-CVD).

7. The method of claim 1, after removing said patterned mask layer further comprising:
performing a semiconductor process on said substrate.

8. The method of claim 7, wherein said semiconductor process is selected from a group consisting of an ion well process, a threshold voltage implantation process, a photoresist-removing process, a cleaning process, a gate structure process and a silicide process.

9. The method of claim 7, wherein said semiconductor process further enlarges said first void and said second void.

10. The method of claim 1, wherein said isolation structure serves as a passing gate isolation (PGI).

11. A semiconductor structure, comprising:
a substrate comprising a first deep trench, a second deep trench and a shallow trench isolation adjacent to said first deep trench and said second deep trench;
a first conductive material partially filling said first deep trench;
a second conductive material partially filling said second deep trench;
a first isolation layer disposed on said first conductive material, filling said first deep trench and partially exposing said first conductive material;
a second isolation layer disposed on said second conductive material, filling said second deep trench and partially exposing said second conductive material, wherein said first isolation layer and said second isolation layer serve as an isolation structure;
a gate structure disposed on at least one of said first isolation layer and said second isolation layer;
a dielectric layer covering said substrate, said first isolation layer, said second isolation layer and said gate structure;
a first contact plug disposed in said dielectric layer and electrically connected to said first conductive material; and
a second contact plug disposed in said dielectric layer and electrically connected to said second conductive material.

12. The semiconductor structure of claim 11, wherein said isolation structure serves as a passing gate isolation (PGI).

13. The semiconductor structure of claim 11, wherein said first isolation layer comprises a single isolation material.

14. The semiconductor structure of claim 11, wherein said first isolation material comprises an oxide.

15. The semiconductor structure of claim 11, wherein said second isolation layer comprises a single isolation material.

16. The semiconductor structure of claim 11, wherein said second isolation material comprises an oxide.

17. The semiconductor structure of claim 11, further comprising a first deep trench extension region and a second deep trench extension region disposed in said substrate and respectively connected to said first deep trench and said second deep trench.

18. The semiconductor structure of claim 11, wherein said first deep trench extension region partially exposes said first conductive material and said second deep trench extension region partially exposes said second conductive material.

19. A method for forming an isolation structure, comprising:
providing a substrate with a shallow trench isolation;
forming a patterned mask layer on said substrate;
etching said substrate through said patterned mask layer to form a first deep trench and a second deep trench respectively on two sides of said shallow trench isolation;
partially filling said first deep trench and said second deep trench with a first conductive material;
filling said first deep trench and said second deep trench with a first isolation material; and
removing said patterned mask layer.

20. The method of claim 19, wherein forming said first deep trench and said second deep trench simultaneously forms a first undercut and a second undercut in said substrate under said patterned mask layer so that said first undercut and said second undercut respectively forms a first void and a second void when removing said patterned mask layer.
